(19) United States
(12) Patent Application Publication
(10) Pub. No.: US 2026/0007053 A1
(43) Pub. Date: Jan. 1, 2026

(54) DISPLAY PANEL AND DISPLAY APPARATUS

(71) Applicant: Hubei Yangtze Industrial Innovation Center Of Advanced Display Co., Ltd., Wuhan (CN)

(72) Inventors: Junqiang WANG, Wuhan (CN); Xuyang FANG, Wuhan (CN); Lingjun DAI, Wuhan (CN)

(73) Assignee: Hubei Yangtze Industrial Innovation Center Of Advanced Display Co., Ltd., Wuhan (CN)

(21) Appl. No.: 19/242,932

(22) Filed: Jun. 18, 2025

(30) Foreign Application Priority Data
Jun. 27, 2024 (CN) 202410846373.4

(51) Int. Cl. H10K 59/80; H10K 59/122; H10K 59/35

(52) U.S. Cl. CPC H10K 59/879; H10K 59/122; H10K 59/352

(57) ABSTRACT

The present disclosure relates to a display panel and a display apparatus. The display panel includes: a first optical adjustment layer located on a side of a light-emitting unit away from a substrate; and a second optical adjustment layer located on a side of the first optical adjustment layer away from the substrate; where a refractive index of the second optical adjustment layer is greater than a refractive index of the first optical adjustment layer; the first optical adjustment layer includes a plurality of first optical adjustment openings and a plurality of second optical adjustment openings. In the present disclosure, the brightness attenuation degree of the light-emitting unit at other viewing angles rather than the normal viewing angle, especially at a large viewing angle can be improved by adding a new second optical adjustment opening on the basis of the original first optical adjustment opening.

### CROSS-REFERENCE TO RELATED APPLICATIONS

This application claims priority to Chinese Patent Application No. 202410846373.4, titled “DISPLAY PANEL AND DISPLAY APPARATUS” and filed on Jun. 27, 2024, which is hereby incorporated by reference in its entirety.

### TECHNICAL FIELD

The present disclosure relates to the field of display technology, and in particular to a display panel and a display apparatus.

### BACKGROUND

Organic Light Emitting Diode (OLED) panel is an active light-emitting display device with the advantages of self-luminescence, wide viewing angle, high contrast, full-color display, light weight, thin thickness, low power consumption, high response speed, etc., and can realize flexible display and is a display device with the most development potential.

### SUMMARY

In order to solve the above technical problems, the present disclosure provides a display panel and a display apparatus.

The present disclosure provides a display panel, including: a substrate; a pixel definition layer located on a side of the substrate, the pixel definition layer comprising a plurality of pixel openings; a plurality of light-emitting units each at least partially located in the pixel opening; a first optical adjustment layer located on a side of the light-emitting unit away from the substrate; a second optical adjustment layer located on a side of the first optical adjustment layer away from the substrate; a refractive index of the second optical adjustment layer being greater than a refractive index of the first optical adjustment layer; where the first optical adjustment layer comprises a plurality of first optical adjustment openings and a plurality of second optical adjustment openings; in a direction perpendicular to a plane where the substrate is located, each of the first optical adjustment openings at least partially overlaps one of the pixel openings; and on the plane where the substrate is located, the orthographic projection of one of the second optical adjustment openings is at least partially located between orthographic projections of adjacent two of the pixel openings.

Based on the same inventive concept, the present disclosure also provides a display apparatus, including a display panel comprising: a substrate; a pixel definition layer located on a side of the substrate, the pixel definition layer comprising a plurality of pixel openings; a plurality of light-emitting units each at least partially located in the pixel opening; a first optical adjustment layer located on a side of the light-emitting unit away from the substrate; a second optical adjustment layer located on a side of the first optical adjustment layer away from the substrate, a refractive index of the second optical adjustment layer being greater than a refractive index of the first optical adjustment layer, wherein the first optical adjustment layer comprises a plurality of first optical adjustment openings and a plurality of second optical adjustment openings; in a direction perpendicular to a plane where the substrate is located, each of the first optical adjustment openings at least partially overlap one of the pixel openings; and on the plane where the substrate is located, an orthographic projection of each of the second optical adjustment openings is at least partially located between orthographic projections of adjacent two of the pixel openings.

### BRIEF DESCRIPTION OF THE DRAWINGS

The drawings herein are incorporated into the specification and constitute a part of the specification, showing embodiments consistent with the present disclosure, and together with the specification, are used to explain the principles of the present disclosure.

In order to more clearly illustrate the technical solutions in the embodiments of the present disclosure or the prior art, the drawings required for use in the embodiments or the prior art description will be briefly introduced below, apparently, for those skilled in this art, other drawings can be obtained based on these drawings without creative labor.

FIG. 1 is a schematic structural cross-sectional view of a part of a display panel in the related art;

FIG. 2 is a white light color trajectory diagram of the display panel in the related art;

FIG. 3 is a schematic structural cross-sectional view of a part of a display panel according to an embodiment of the present disclosure;

FIG. 4 is a schematic structural planar view of a part of the display panel according to an embodiment of the present disclosure;

FIG. 5 is a white light color trajectory diagram of the display panel provided in an embodiment of the present disclosure and the display panel in the related art;

FIG. 6 is a JNCD curve diagram of the display panel provided in an embodiment of the present disclosure and the display panel in the related art;

FIG. 7 is a red light-emitting unit brightness attenuation curve diagram of the display panel provided in an embodiment of the present disclosure and the display panel in the related art;

FIG. 8 is a green light-emitting unit brightness attenuation curve diagram of the display panel provided in an embodiment of the present disclosure and the display panel in the related art;

FIG. 9 is a blue light-emitting unit brightness attenuation curve diagram of the display panel provided in an embodiment of the present disclosure and the display panel in the related art;

FIG. 10 is a schematic structural planar view of a part of another display panel according to an embodiment of the present disclosure;

FIG. 11 is a schematic principle diagram of a micro lens provided by an embodiment of the present disclosure;

FIG. 12 is a schematic structural planar view of a part of another display panel according to an embodiment of the present disclosure;

FIG. 13 is a schematic structural planar view of a part of another display panel according to an embodiment of the present disclosure;

FIG. 14 is a schematic principle diagram of another micro lens provided by an embodiment of the present disclosure;

FIG. 15 is a schematic structural planar view of a part of another display panel according to an embodiment of the present disclosure;

FIG. 16 is a schematic structural planar view of a part of another display panel according to an embodiment of the present disclosure;

FIG. 17 is a schematic structural planar view of a part of another display panel according to an embodiment of the present disclosure;

FIG. 18 is a schematic structural planar view of a part of another display panel according to an embodiment of the present disclosure;

FIG. 19 is a schematic structural planar view of a part of another display panel according to an embodiment of the present disclosure;

FIG. 20 is a schematic structural planar view of a part of another display panel according to an embodiment of the present disclosure; and

FIG. 21 is a schematic structural planar view of a display apparatus provided by an embodiment of the present disclosure.

### DETAILED DESCRIPTION

In order to more clearly understand the above-mentioned purpose, features and advantages of the embodiments of the present disclosure, the scheme of the embodiments of the present disclosure will be further described below. It should be noted that, in the absence of conflict, the embodiments of the present disclosure and the features in the embodiments can be combined with each other.

In the following description, many specific details are explained to facilitate a full understanding of the embodiments of the present disclosure, but the embodiments of the present disclosure can also be implemented in other ways different from those described herein; apparently, the embodiments in the specification are only part of the embodiments of the present disclosure, rather than all of the embodiments.

For the OLED display panel, a micro lens (Micro Lens Panel, MLP) can be additionally arranged above the light-emitting unit to change the propagation direction of the emitted light through the refraction of the micro lens, thereby improving the front light emission efficiency of the OLED display panel.

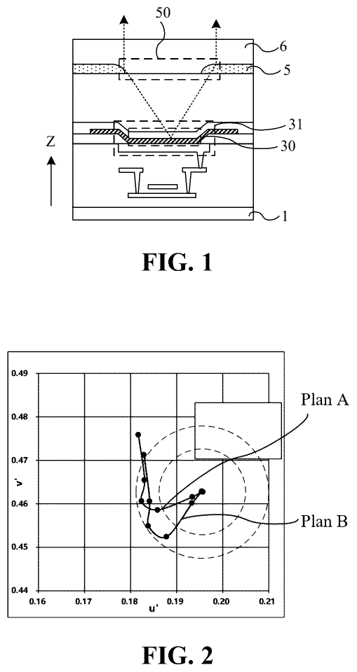

Specifically, FIG. 1 shows a cross-sectional structure of a display panel, including a substrate 1, a pixel opening 30 located on one side of the substrate 1 (a light-emitting unit 31 is located in the pixel opening and may be an OLED), a first optical adjustment layer 5 located on one side of the pixel opening 30 away from the substrate 1, and a second optical adjustment layer 6 located on one side of the first optical adjustment layer 5 away from the substrate 1. Herein, a refractive index of the second optical adjustment layer 6 is greater than a refractive index of the first optical adjustment layer 5, the first optical adjustment layer 5 includes a plurality of optical adjustment openings 50, the second optical adjustment layer 6 fills the optical adjustment openings 50, the first optical adjustment layer 5 and the second optical adjustment layer 6 jointly constitute a micro lens, and in a direction Z perpendicular to a plane where the substrate 1 is located, the optical adjustment opening 50 corresponds to the pixel opening 30.

As shown in FIG. 1, since the refractive index of the second optical adjustment layer 6 is greater than the refractive index of the first optical adjustment layer 5, the light emitted from the light-emitting unit 31 in the pixel opening 30 can be refracted and totally reflected at a junction of the first optical adjustment layer 5 and the second optical adjustment layer 6, thereby causing the light emitted originally at a large angle to be deflected to a small angle (i.e., a normal viewing angle), thereby improving the front light emission efficiency of the OLED display panel. MLP technology not only enhances the screen brightness, but also helps to reduce energy loss due to the improvement of light energy utilization efficiency, thereby achieving the purpose of reducing screen power consumption.

Although MLP technology improves the front view brightness and energy efficiency of the display panel through the micro lenses, it may cause the display panel to have a certain dependence on the viewing angle, such as causing the color offset or the brightness attenuation when the user views the display panel at a larger viewing angle. FIG. 2 shows white light color trajectories of a conventional display panel (Plan A) and a display panel (Plan B) with MLP added. The center of the dotted circle in the figure is the white light reference point. It can be seen that compared with the conventional display panel, the display panel with MLP added has a significant deviation in the white light color trajectory with respect to the reference point.

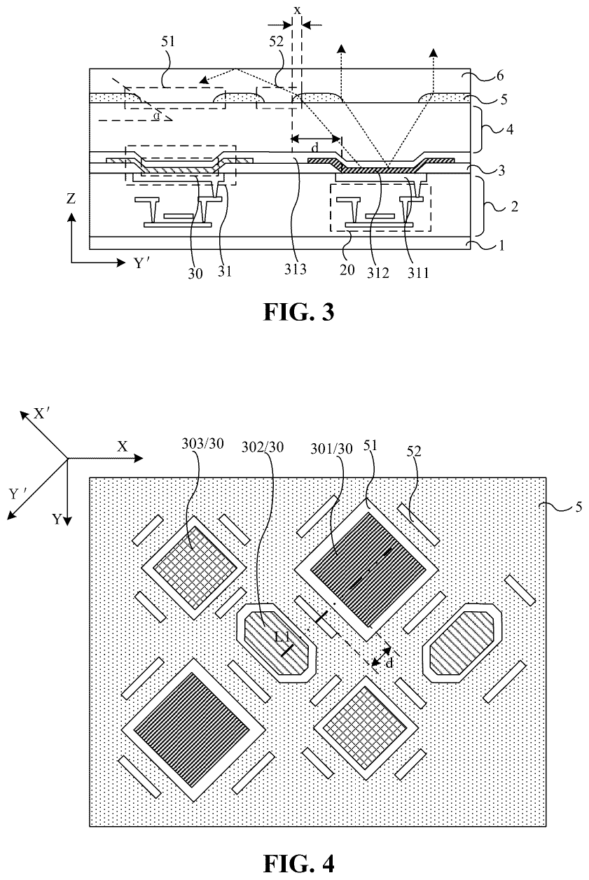

In view of this, the embodiment of the present disclosure provides a display panel, as shown in FIG. 3, which includes a substrate 1, a pixel definition layer 3 and a plurality of light-emitting units 31, the pixel definition layer 3 being located on one side of the substrate 1 and including a plurality of pixel openings 30, and the light-emitting unit 31 being at least partially located in the pixel opening 30.

Specifically, as shown in FIG. 3, the light-emitting unit 31 specifically includes an anode 311, a cathode 313 and a light-emitting layer 312 located between the anode 311 and the cathode 313, and the light-emitting layer 312 refers to a layer that emits light in the light-emitting unit 31. The light-emitting unit 31 may also include structures such as a hole transport layer, a hole injection layer, an electron transport layer, and an electron injection layer. The display panel also includes a driving circuit layer 2 including a pixel driving circuit 20 electrically connected with the anode 311 of the light-emitting unit 31. The light-emitting layer 312 in the light-emitting unit 31 receives an electrical signal provided by the pixel driving circuit 20 through the anode 311, and generates an electroluminescence, thereby forming a sub-pixel in the display panel.

The display panel also includes a first optical adjustment layer 5 located on one side of the pixel opening 30 away from the substrate 1 and a second optical adjustment layer 6 located on one side of the first optical adjustment layer 5 away from the substrate 1. The refractive index of the second optical adjustment layer 6 is greater than an refractive index of the first optical adjustment layer 5, the first optical adjustment layer 5 includes a plurality of first optical adjustment openings 51 and a plurality of second optical adjustment openings 52, a material of the second optical adjustment layer 6 fills the plurality of first optical adjustment openings 51 and the plurality of second optical adjustment openings 52, and the first optical adjustment layer 5 and the second optical adjustment layer 6 jointly constitute a plurality of micro lenses.

As shown in FIG. 3, in a direction Z perpendicular to a plane where the substrate is located, the first optical adjustment opening 51 and the pixel opening 30 at least partially overlap. FIG. 4 shows a top view of a plane where the substrate is located in an embodiment (FIG. 3 is a cross-sectional view of the display panel shown in FIG. 4 along a cutting line L1), the pixel openings 30 include a first pixel opening 301, a second pixel opening 302 and a third pixel opening 303, and on the plane where the substrate is located, the orthographic projection of the second optical adjustment opening 52 is at least partially located between orthographic projections of adjacent two of the pixel openings 30.

As shown in FIG. 3, after the second optical adjustment opening 52 is added, at a large viewing angle, a portion of the emitted light of the light-emitting unit 31 in the pixel opening 30 may be totally reflected at an interface between the second optical adjustment layer 6 and the air or the upper thin film, thereby adjusting the attenuation degree of the light-emitting unit 31 at a large viewing angle. According to the original white light color trajectories of different display panels, the white light color trajectories of the display panels may be specifically adjusted to the expected direction through the second optical adjustment opening 52.

In a specific embodiment, as shown in FIG. 5 to FIG. 9, FIG. 5 shows white light color trajectories of a conventional display panel (Plan A), a conventional MLP display panel (Plan B) and a display panel (Plan C) of the embodiment in the present disclosure. The center of the dotted circle in the figure is the white light reference point. It can be seen that compared with the conventional display panel, the conventional MLP display panel has a significant deviation in the white light color trajectory with respect to the reference point, but the display panel of the embodiments in the present disclosure improves the deviation degree of the white light color trajectory.

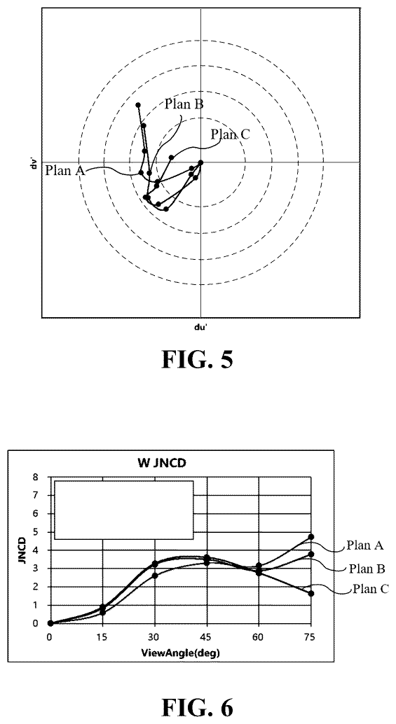

FIG. 6 shows JNCD simulation diagrams of a conventional display panel (Plan A), a conventional MLP display panel (Plan B), and a display panel (Plan C) of the embodiment in the present disclosure. JNCD (Just Noticeable Color Difference) is an indicator for measuring a color accuracy of a display. The lower the JNCD value is, the higher the color accuracy of the display panel is and the better the display effect is. It can be seen that compared with conventional display panels, conventional MLP display panels reduce the JNCD value of the display panel, and the display panel of the embodiment of the present disclosure further reduces the JNCD value of the display panel.

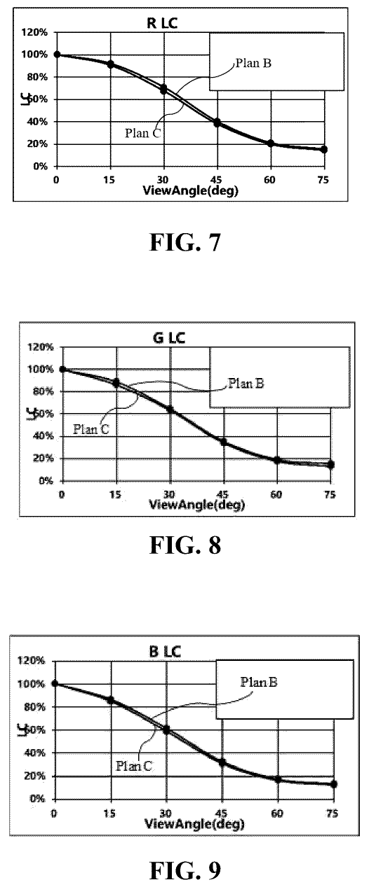

The light-emitting units in the display panel include red light-emitting units, green light-emitting units, and blue light-emitting units. FIG. 7 shows brightness attenuation curves of the red light-emitting units in the conventional MLP display panel (Plan B) and the display panel (Plan C) of the embodiment in the present disclosure at different viewing angles. FIG. 8 shows brightness attenuation curves of the green light-emitting units in the conventional MLP display panel (Plan B) and the display panel (Plan C) of the embodiment in the present disclosure at different viewing angles. FIG. 9 shows brightness attenuation curves of the blue light-emitting units in the conventional MLP display panel (Plan B) and the display panel (Plan C) of the embodiment in the present disclosure at different viewing angles. It can be seen that in this embodiment, the second optical adjustment opening 52 accelerates the brightness attenuation of the red light-emitting units, the green light-emitting units, and the blue light-emitting units. However, the brightness attenuation degrees of the red light-emitting units, the green light-emitting units, and the blue light-emitting units affected by the second optical adjustment opening 52 are different, thereby improving the white light color trajectories of the display panels and achieving the improvement effect shown in FIG. 5.

In the embodiments of the present disclosure, the brightness attenuation degree of the light-emitting unit 31 at other viewing angles rather than the normal viewing angle, especially at a large viewing angle can be improved by adding a new second optical adjustment opening 52 on the basis of the original first optical adjustment opening 51, thereby optimizing the white light color trajectory of the display panel and improving the display effect of the display panel at a large viewing angle.

It can be understood that the shapes, size ratios and arrangements of the orthographic projections of the pixel opening 30, the first optical adjustment opening 51 and the second optical adjustment opening 52 shown in FIG. 4 are all exemplary. Based on the above-mentioned description, those skilled in the art can apply the embodiments of the present disclosure to display panels with pixel openings of other shapes; and, since the shapes, sizes and arrangements of the pixel openings of different display panels are different, the shapes and sizes of the orthographic projections of the first optical adjustment openings and the second optical adjustment openings are changed according to the pixel openings of different display panels, which are all within the protection scope of the present disclosure.

In specific implementation, as shown in FIG. 3, the display panel further includes an intermediate medium layer 4 between the pixel definition layer 3 and the first optical adjustment layer 5, and the intermediate medium layer 4 allows the emitted light of the light-emitting unit 31 to pass through.

In a specific implementation, in a direction Z perpendicular to a plane where the substrate is located, a thickness of the first optical adjustment layer 5 ranges from 1 micron to 4 microns, and a thickness of the second optical adjustment layer 6 at the first optical adjustment opening 51 and the second optical adjustment opening 52 is greater than the thickness of the first optical adjustment layer 5.

In a specific implementation, the first optical adjustment layer 5 and the second optical adjustment layer 6 may include materials such as acrylates, epoxy resins, and polyurethanes.

In a specific implementation, as shown in FIG. 4, on the plane where the substrate is located, a shape of the orthographic projection of the first optical adjustment opening 51 is similar to a shape of the orthographic projection of the corresponding pixel opening 30. The distance between the edge of the orthographic projection of the first optical adjustment opening and the edge of the orthographic projection of the corresponding pixel opening ranges from 0 microns to 2 microns, and the area of the orthographic projection of the first optical adjustment opening 51 is greater than the area of the orthographic projection of the corresponding pixel opening 30.

In some embodiments, as shown in FIG. 4, on the plane where the substrate is located, at least one edge of the orthographic projection of the first optical adjustment opening 51 is parallel to at least one edge of the orthographic projection of the adjacent second optical adjustment opening 52.

The second optical adjustment opening 52 does not overlap the first optical adjustment opening 51 or the pixel opening 30 in the direction Z perpendicular to the plane where the substrate is located. That is, the second optical adjustment opening 52 needs to be manufactured in the non-luminous area of the display panel, so that the edge of the second optical adjustment opening 52 is parallel to the edge of the first optical adjustment opening 51, which can maximize the use of the non-luminous area of the display panel and prevent the aperture ratio of the display panel from being affected by newly added second optical adjustment openings 52, thereby improving the display effect and the service life of the display panel.

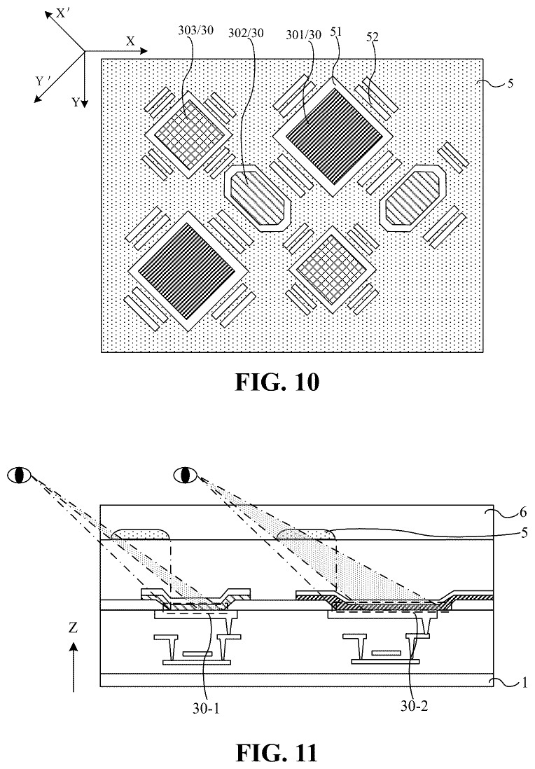

In some embodiments, as shown in FIG. 10, on the plane where the substrate is located, the orthographic projections of at least two of the second optical adjustment openings 52 are located between orthographic projections of two of the pixel openings 30.

By increasing the number of second optical adjustment openings 52 between the two pixel openings 30, the brightness attenuation degree of the light-emitting unit 31 at a large viewing angle can be further improved.

Those skilled in the art can arrange a larger number of second optical adjustment openings 52 between the two pixel openings 30 based on the above-mentioned embodiments, which will not be described in detail here.

In some embodiments, as shown in FIG. 3, the sidewalls of the first optical adjustment openings 51 and the second optical adjustment openings 52 formed by the first optical adjustment layer 5 include curved sidewalls protruding toward the second optical adjustment layer 6, so that part of the emitted light of the light-emitting unit 31 can be totally reflected at a junction of the first optical adjustment layer 5 and the second optical adjustment layer 6, and the emitted light after total reflection is biased toward the normal viewing angle.

In some embodiments, as shown in FIG. 3, there is an included angle a between at least one tangent line of the curved sidewall and the plane where the substrate is located form an included angle a in a range of 65° to 85°, so as to ensure that part of the emitted light of the light-emitting unit 31 can be totally reflected at the junction of the first optical adjustment layer 5 and the second optical adjustment layer 6, and the emitted light after total reflection is biased toward the normal viewing angle, and the above-mentioned included angle a can achieve a better light effect improvement effect.

In some embodiments, as shown in FIG. 3, the display panel further includes at least one intermediate medium layer 4 located between the first optical adjustment layer 5 and the pixel definition layer 3.

Specifically, the display panel may only include one intermediate medium layer 4 made of a single material, or may include multiple intermediate medium layers 4 made of different materials, and all intermediate medium layers 4 can transmit the emitted light of the light-emitting unit 31.

As shown in FIG. 3 and FIG. 4, in a preset direction Y′, a distance d between an edge of one second optical adjustment opening 52 and an edge of the pixel opening 30 corresponding to the adjacent first optical adjustment opening 51 is in a value range of:

$$x + {\sum }_{i = 1}^{k} {h}_{i} * tan ( asin ( sin ( θ1 ) / {n}_{i} ) ) \leq d \leq x + {\sum }_{i = 1}^{k} {h}_{i} * tan ( asin ( sin ( θ2 ) / {n}_{i} ) )$$

where x is a length of the curved sidewall in the preset direction Y′, k is a number of the intermediate medium layers, hᵢ is a thickness of the i-th layer of the intermediate medium layers 4 in a direction Z, nᵢ is a material refractive index of the i-th layer of the intermediate medium layers 4, θ1 is a lower limit of an optical adjustment angle, θ2 is an upper limit of an optical adjustment angle, θ1≤θ2, a value range of θ1 is 55° to 65°, for example, 60°, a value range of θ2 is 80° to 90°, for example, 85°. The preset direction is parallel to the plane where the substrate 1 is located and points from the second optical adjustment opening 52 to the adjacent first optical adjustment opening 51.

Specifically, the distance d determined according to the formula in the above-mentioned embodiment can improve the brightness attenuation degree of the display panel with a viewing angle between “θ1” and “θ2”, so the above “θ1” and “θ2” define a larger angle range.

In specific implementation, since not each pixel opening in the OLED panel has exactly the same size, the micro lens has different brightness attenuation effects on the light-emitting units 31 in different pixel openings. Specifically, as shown in FIG. 11, the display panel includes two light-emitting units, the sizes (specifically, the areas) of the pixel openings 30-1 and 30-2 are different. At the same viewing angle, most of the emitted light of the light-emitting unit 31 in the pixel opening 30-2 with a larger size can be deflected toward the normal viewing angle through the micro lens structure, while only a small part of the emitted light of the light-emitting unit 31 in the pixel opening 30-1 with a smaller size can be deflected toward the normal viewing angle through the micro lens structure. This results in different brightness attenuation speeds of light-emitting units 31 with different sizes as the viewing angle changes. Moreover, the sizes of light-emitting units 31 with different colors in the display panel are usually different, which may further lead to the deviation of the color trajectory of the OLED display panel, causing the display color shift problem.

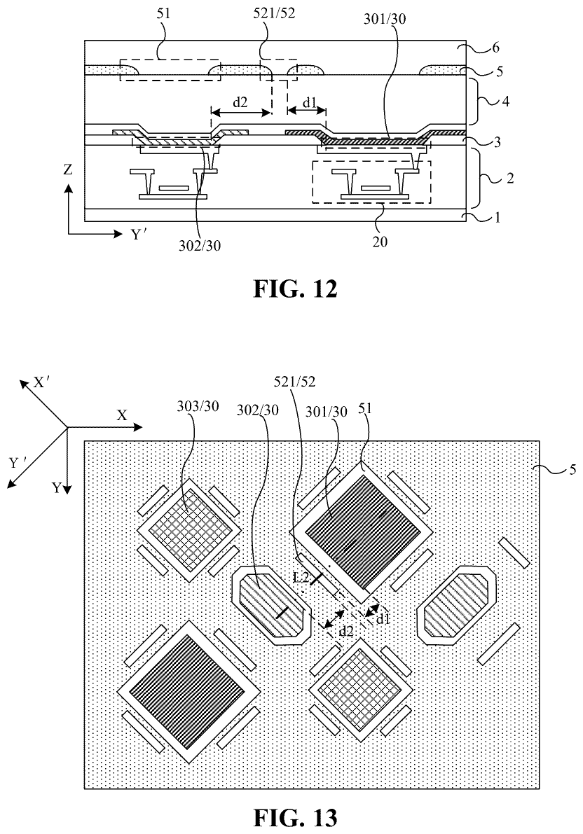

In view of this, in some embodiments, as shown in FIG. 12 and FIG. 13, in which FIG. 12 is a cross-sectional view of the display panel shown in FIG. 13 along the cutting line L2, the pixel openings 30 includes a first pixel opening 301 and a second pixel opening 302 adjacent with each other; on the plane where the substrate is located, an area of the orthographic projection of the first pixel opening 301 is different from an area of the orthographic projection of the second pixel opening 302.

The second optical adjustment openings 52 include a second first optical adjustment opening 521; on the plane where the substrate is located, the orthographic projection of the second first optical adjustment opening 521 is located between the orthographic projection of the first pixel opening 301 and the orthographic projection of the second pixel opening 302.

On the plane where the substrate is located, the distance between the edge of the orthogonal projection of the second first optical adjustment opening 521 close to the first pixel opening 301 and the edge of the orthogonal projection of the first pixel opening 301 close to the second first optical adjustment opening 521 is the first distance d1, and the distance between an edge of the orthogonal projection of the second first optical adjustment opening 521 close to the second pixel opening 302 and an edge of the orthogonal projection of the second pixel opening 302 close to the second first optical adjustment opening 521 is the second distance d2, the first distance dl being different from the second distance d2. In other words, the distance between the second first optical adjustment opening 521 and the first pixel opening 301 is different from the distance between the second first optical adjustment opening 521 and the second pixel opening 302.

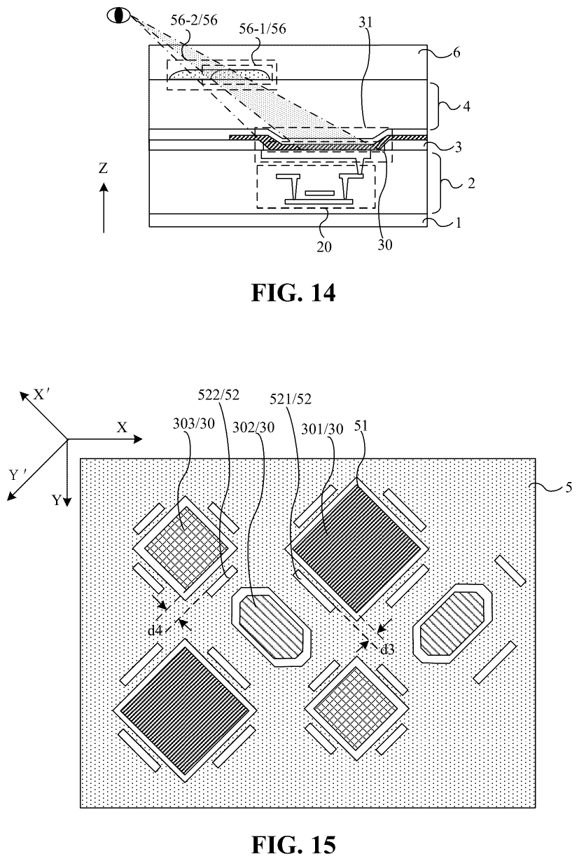

The distance from the second optical adjustment opening to the pixel opening can be reflected as the size of the micro lens constructed by the first optical adjustment layer and the second optical adjustment layer. The embodiment of FIG. 14 shows a schematic diagram of the light effect improvement of the same pixel opening 30 by micro lenses 56 of different sizes (a first micro lens 56-1 with a smaller size and a second micro lens 56-2 with a larger size). It can be seen from the figure that at the same viewing angle, the proportions of the emitted light on which micro lenses 56 of different sizes can act to the total emitted light of the pixel opening are different, thereby achieving different light effect improvement effects. Specifically, for a pixel opening, the farther the second optical adjustment opening 52 is from the pixel opening, the more emitted light of the pixel opening is deflected by the second optical adjustment opening 52, and the faster the brightness attenuation is at a large angle. Therefore, for pixel openings with different orthographic projection areas, the distances from the second optical adjustment openings to the pixel openings are different, and targeted light effect improvement can be performed for different pixel openings, specifically, the brightness attenuation of the light-emitting units in some pixel openings is accelerated in a targeted manner, thereby improving the display color shift problem caused by the deviation of the color trajectory of the display panel at a large angle.

It should be noted that in the related art, there is no unified standard for the final display effect of the display panel. According to the different needs of users, the color trajectory of the final display panel shipped can still deviate according to customer needs, and the direction of the deviation can also be different. Therefore, the above-mentioned first distance may be greater than the second distance, or may be less than the second distance. Those skilled in the art can set the relationship between the above-mentioned first distance and the second distance based on the above-mentioned embodiments and the schematic principle diagram shown in FIG. 14, and achieve the corresponding technical effect, which is within the protection scope of the embodiments of the present disclosure.

It can be understood that the above-mentioned first distance dl may be the shortest distance between the edge of the orthogonal projection of the second first optical adjustment opening 521 close to the first pixel opening 301 and the edge of the orthogonal projection of the first pixel opening 301 close to the second first optical adjustment opening 521, and the second distance d2 may be the shortest distance between the edge of the orthogonal projection of the second first optical adjustment opening 521 close to the second pixel opening 302 and the edge of the orthogonal projection of the second pixel opening 302 close to the second first optical adjustment opening 521. And, taking the first distance d1 as an example, when the edge of the orthographic projection of the second first optical adjustment opening 521 close to the first pixel opening 301 is parallel to the edge of the orthographic projection of the first pixel opening 301 close to the second first optical adjustment opening 521, the first distance d1 may be a vertical distance between the two. In other embodiments, the orthographic projections of the second first optical adjustment opening 521 and the first pixel opening 301 on the plane where the substrate is located are both circular, and the above-mentioned first distance dl can be the shortest distance between two endpoints which are determined by the edges of the second first optical adjustment opening 521 and the first pixel opening 301 respectively. The other embodiments of the present disclosure involve the distances in the same way, which will not be repeated in detail.

In a specific embodiment, as shown in FIGS. 12 and 13, on the plane where the substrate is located, an area of the orthographic projection of the first pixel opening 301 is greater than an area of the orthographic projection of the second pixel opening 302; the first distance d1 is less than the second distance d2. In other words, the second first optical adjustment opening 521 is closer to the first pixel opening 301 and farther from the second pixel opening 302.

It can be seen from the embodiment shown in FIG. 11 that, at the same viewing angle, most of the emitted light of the light-emitting unit 31 in the pixel opening 30-2 with a larger size can be deflected toward the normal viewing angle through the micro lens structure, while only a small part of the emitted light of the light-emitting unit 31 in the pixel opening 30-1 with a smaller size can be deflected toward the normal viewing angle through the micro lens structure. That is to say, in the conventional MLP display panel, the brightness attenuation speed of the light-emitting unit in the pixel opening with a larger size is faster at a large angle, which leads to the problem of color trajectory deviation; it can be seen from the embodiment shown in FIG. 14 that for a pixel opening, the farther the second optical adjustment opening is from the pixel opening, the more emitted light of the pixel opening is deflected by the micro lens, and the faster the brightness attenuation is at a large angle. Since the brightness attenuation speed of the light-emitting unit in the pixel opening with a larger size is faster at a large angle under normal circumstances, the display panel of the embodiment of the present disclosure can accelerate the brightness attenuation of the light-emitting unit in the pixel opening with a small size at a large viewing angle by making the second optical adjustment opening farther from the pixel opening with a small size, thereby making the brightness attenuation speeds of the light-emitting units in the pixel openings of different sizes approximately the same at a large viewing angle, so as to improve the color shift problem.

In some embodiments, a red light-emitting unit or a blue light-emitting unit is located in the first pixel opening 301, and a green light-emitting unit is located in the second pixel opening 302.

Optionally, an area of the orthographic projection of each pixel opening can be set according to the light-emitting efficiency of the light-emitting material in the pixel opening. For example, if the light-emitting efficiency of the material is higher, the area of the pixel opening may be smaller, and if the light-emitting efficiency of the material is lower, the area of the pixel opening may be larger. In this way, on the basis of the same driving current, the pixel opening with a larger area can have similar light-emitting brightness as the pixel opening with a smaller area.

Since the light-emitting efficiency of the green organic light-emitting material is higher than that of the red organic light-emitting material and the blue organic light-emitting material, in some embodiments, an area of the pixel opening of the blue light-emitting unit and an area of the pixel opening of the red light-emitting unit are larger than an area of the pixel opening of the green light-emitting unit.

Optionally, an area of the orthographic projection of each pixel opening can be set according to the service life of the light-emitting material in the pixel opening. For example, if the service life of the material is better, the area of the pixel opening may be smaller, and if the service life of the material is worse, the area of the pixel opening may be larger. In this way, the light-emitting unit with a pixel opening larger in area can use a smaller driving current to achieve a higher light-emitting brightness, thereby extending the light-emitting life of the light-emitting unit.

Since the service life of the green organic light-emitting material is better than that of the red organic light-emitting material and that of the blue organic light-emitting material, in some embodiments, the area of pixel opening of the blue light-emitting unit and the area of pixel opening of the red light-emitting unit are larger than the area of pixel opening of the green light-emitting unit.

In some embodiments, as shown in FIG. 15, the pixel openings 30 include a first pixel opening 301, a second pixel opening 302 and a third pixel opening 303, and the first pixel opening 301 and the third pixel opening 303 both are adjacent to the second pixel opening 302.

On the plane where the substrate is located, an area of the orthographic projection of the first pixel opening 301 is larger than an area of the orthographic projection of the third pixel opening 303, and an area of the orthographic projection of the third pixel opening 303 is larger than an area of the orthographic projection of the second pixel opening 302.

Optionally, the area of orthographic projection of each pixel opening can be set according to the light-emitting efficiency of the light-emitting material in the pixel opening. For example, if the light-emitting efficiency of the material is higher, the area of the pixel opening may be smaller, and if the light-emitting efficiency of the material is lower, the area of the pixel opening may be larger. In this way, on the basis of the same driving current, the pixel opening with a larger area can have similar light-emitting brightness as the pixel opening with a smaller area.

Since the light-emitting efficiency of the green organic light-emitting material is higher than that of the red organic light-emitting material, and the light-emitting efficiency of the red organic light-emitting material is higher than that of the blue organic light-emitting material, in some embodiments, a green light-emitting unit is located in the second pixel opening, a red light-emitting unit is located in the third pixel opening, and a blue light-emitting unit is located in the first pixel opening.

Optionally, the area of the orthographic projection of each pixel opening can be set according to the service life of the light-emitting material in the pixel opening. For example, if the service life of the material is better, the area of the pixel opening may be smaller, and if the service life of the material is worse, the area of the pixel opening may be larger. In this way, the light-emitting unit of the pixel opening with a larger area can use a smaller driving current to achieve a higher light-emitting brightness, thereby extending the light-emitting service life of the light-emitting unit.

Since the service life of the green organic light-emitting material is better than that of the red organic light-emitting material, and the service life of the red organic light-emitting material is better than that of the blue organic light-emitting material, in some embodiments, a green light-emitting unit is located in the second pixel opening, a red light-emitting unit is located in the third pixel opening, and a blue light-emitting unit is located in the first pixel opening.

In some embodiments, as shown in FIG. 15, the second optical adjustment opening 52 includes a second first optical adjustment opening 521 and a second second optical adjustment opening 522. On the plane where the substrate is located, the orthographic projection of the second first optical adjustment opening 521 is located between the orthographic projection of the first pixel opening 301 and the orthographic projection of the second pixel opening 302, and the orthographic projection of the second second optical adjustment opening 522 is located between the orthographic projection of the third pixel opening 303 and the orthographic projection of the second pixel opening 302.

On the plane where the substrate is located, an area of the orthographic projection of the second first optical adjustment opening 521 is larger than an area of the orthographic projection of the second second optical adjustment opening 522.

An area of the orthographic projection of the first pixel opening 301 is greater than an area of the orthographic projection of the third pixel opening 303, which means that a length of at least one edge of the orthographic projection of the first pixel opening 301 is greater than a length of one of edges of the orthographic projection of the third pixel opening 303. In order to make the second optical adjustment opening 52 evenly improve all the emitted light of the light-emitting unit in a pixel opening 30, the size of the second optical adjustment opening 52 need to be adapted to the size of the adjacent pixel opening 30, which is specifically reflected in that the length of the edge of the orthographic projection of the second first optical adjustment opening 521 close to the first pixel opening 301 is greater than the length of the edge of the orthographic projection of the second second optical adjustment opening 522 close to the third pixel opening 303, and thus an area of the orthographic projection of the second first optical adjustment opening 521 is greater than an area of the orthographic projection of the second second optical adjustment opening 522.

Therefore, the length of the edge of the orthographic projection of the above-mentioned second first optical adjustment opening 521 close to the first pixel opening 301 is greater than the length of the edge of the orthographic projection of the second second optical adjustment opening 522 close to the third pixel opening 303. When the widths of the second first optical adjustment opening 521 and the second second optical adjustment opening 522 perpendicular to the above-mentioned length direction are similar, the area of orthographic projection of the second first optical adjustment opening 521 may be greater than the area of orthographic projection of the second second optical adjustment opening 522.

In some embodiments, as shown in FIG. 15, the second optical adjustment opening 52 includes a second first optical adjustment opening 521 and a second second optical adjustment opening 522. On the plane where the substrate is located, the orthographic projection of the second first optical adjustment opening 521 is located between the orthographic projection of the first pixel opening 301 and the orthographic projection of the second pixel opening 302, and the orthographic projection of the second second optical adjustment opening 522 is located between the orthographic projection of the third pixel opening 303 and the orthographic projection of the second pixel opening 302.

On the plane where the substrate is located, the distance between the edge of the orthographic projection of the second first optical adjustment opening 521 close to the first pixel opening 301 and the edge of the orthographic projection of the first pixel opening 301 close to the second first optical adjustment opening 521 is a third distance d3, and the distance between the edge of the orthographic projection of the second second optical adjustment opening 522 close to the third pixel opening 303 and the edge of the orthographic projection of the third pixel opening 303 close to the second second optical adjustment opening 522 is a fourth distance d4, the third distance d3 being less than the fourth distance d4. In other words, the distance between the second first optical adjustment opening 521 and the first pixel opening 301 is smaller than the distance between the second second optical adjustment opening 522 and the third pixel opening 303.

It can be seen from the embodiment shown in FIG. 11 that, at the same viewing angle, most of the emitted light of the light-emitting unit 31 in the pixel opening 30-2 with a larger size can be deflected toward the normal viewing angle through the micro lens structure, while only a small part of the emitted light of the light-emitting unit 31 in the pixel opening 30-1 with a smaller size can be deflected toward the normal viewing angle through the micro lens structure. That is to say, in the conventional MLP display panel, the brightness attenuation speed of the light-emitting unit in the pixel opening with a larger size is faster at a large angle, which leads to the problem of color trajectory deviation; it can be seen from the embodiment shown in FIG. 14 that for a pixel opening, the farther the second optical adjustment opening is from the pixel opening, the more emitted light of the pixel opening is deflected by the micro lens, and the faster the brightness attenuation is at a large angle. Since the brightness attenuation speed of the light-emitting unit in the pixel opening with a larger size is faster at a large angle under normal circumstances, the display panel of the embodiments of the present disclosure can accelerate the brightness attenuation of the light-emitting unit in the pixel opening with a small size at a large viewing angle by making the second optical adjustment opening farther from the pixel opening with a small size, thereby making the brightness attenuation speeds of the light-emitting units in the pixel openings of different sizes approximately the same at a large viewing angle, so as to improve the color shift problem.

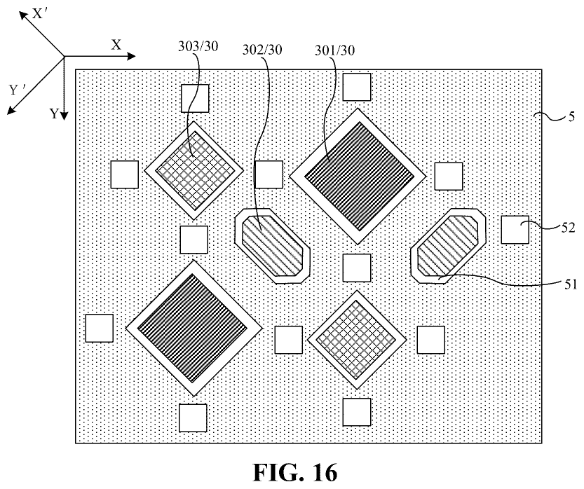

In some embodiments, as shown in FIG. 16, the third pixel openings 303 and the first pixel openings 301 are arranged alternately along the first direction X and the second direction Y each, the third pixel openings 303 and the second pixel openings 302 are arranged alternately along the third direction X′, and the first pixel openings 301 and the second pixel openings 302 are arranged alternately along the fourth direction Y′, where the first direction X, the second direction Y, the third direction X′ and the fourth direction Y′ intersect with each other. In a specific embodiment, the first direction X and the second direction Y are perpendicular to each other, the third direction X′ and the fourth direction Y′ are perpendicular to each other, the acute angle between the first direction X and the third direction X′ is 45°, and the acute angle between the second direction Y and the fourth direction Y′ is 45°.

The above-mentioned arrangement of pixel openings enables each pixel opening to be surrounded by the other two pixel openings, which can make the color of the display image of the display panel more delicate. Specifically, a green light-emitting unit is located in the second pixel opening, a red light-emitting unit is located in the third pixel opening, and a blue light-emitting unit is located in the first pixel opening. In the above-mentioned arrangement of pixel openings, the green light-emitting unit is surrounded by the red light-emitting unit and the blue light-emitting unit. Since the human eye is more sensitive to green, the above-mentioned arrangement can reduce the jagged-edge sense of the pixels, thereby optimizing the display effect of the display panel.

In some embodiments, as shown in FIG. 16, on the plane where the substrate is located, the orthographic projection of a second optical adjustment opening 52 is located between the orthographic projections of the two second pixel openings 302, and between the orthographic projection of the first pixel opening 301 and the orthographic projection of the third pixel opening 303, which is equivalent to that the light-emitting units of the adjacent two of the second pixel openings 302 and the light-emitting units of the first pixel opening 301 and the third pixel opening 303 that are adjacent share a second optical adjustment opening 52 for optical adjustment.

Specifically, in the above embodiments, the orthographic projection of one second optical adjustment opening 52 is simultaneously located between the orthographic projections of two of the second pixel openings 302 and between the orthographic projection of the first pixel opening 301 and the orthographic projection of the third pixel opening 303. While improving the brightness attenuation degree of the large-angle emitted light of the light-emitting unit, the number of second optical adjustment openings 52 in the entire display panel is reduced to prevent the aperture ratio of the display panel from being affected by newly added second optical adjustment openings 52, thereby improving the display effect and the service life of the display panel.

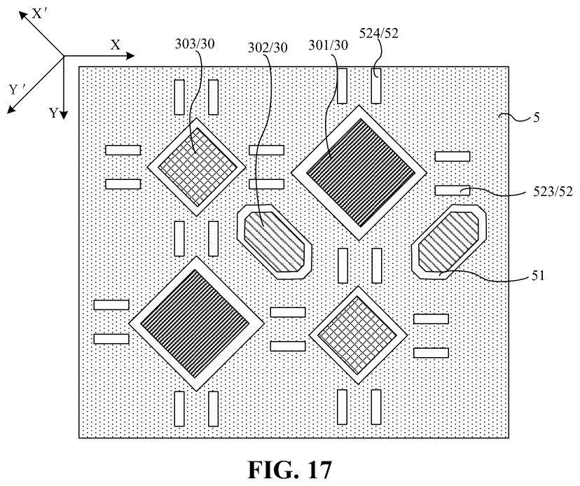

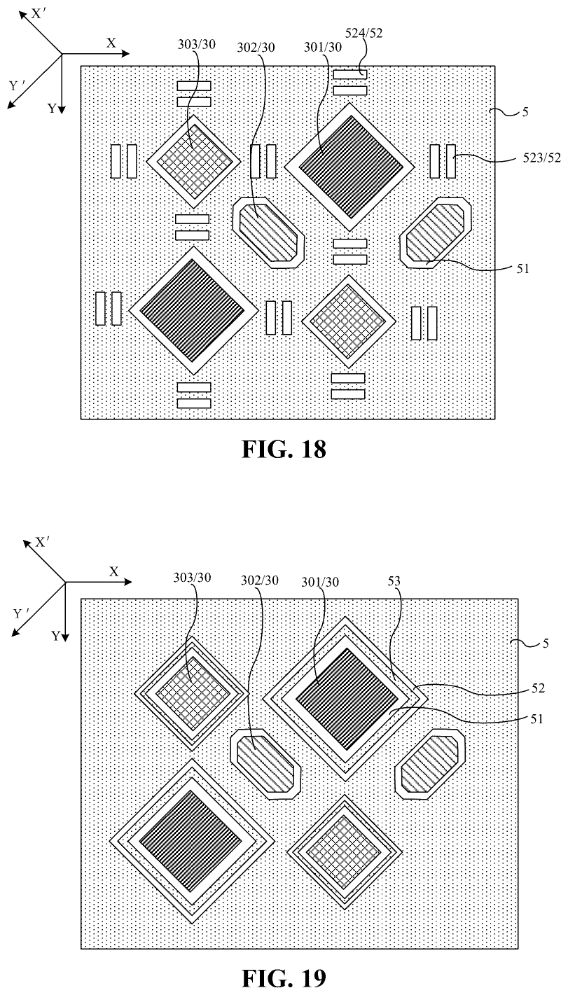

In some embodiments, as shown in FIG. 17 and FIG. 18, on the plane where the substrate is located, the orthographic projections of at least two of the second optical adjustment openings 52 are located between the orthographic projections of two of the second pixel openings 302, and the orthographic projections of at least two of the second optical adjustment openings 52 are located between the orthographic projection of the first pixel opening 301 and the orthographic projection of the third pixel opening 303, thereby further improving the brightness attenuation degree of the light-emitting unit at a large viewing angle by increasing the number of second optical adjustment openings 52 between the two pixel openings 30.

Specifically, in the embodiment shown in FIG. 17, the second optical adjustment openings 52 include a second third optical adjustment opening 523 and a second fourth optical adjustment opening 524. On the plane where the substrate is located, the orthographic projection of at least one second third optical adjustment opening 523 is located between two respective orthographic projections of the first pixel openings 301 and the third pixel openings 303 arranged alternately along the first direction X, and the orthographic projection of at least one second fourth optical adjustment opening 524 is located between two respective orthographic projections of the first pixel openings 301 and the third pixel openings 303 arranged alternately along the second direction Y.

On the plane where the substrate is located, the orthogonal projections of the second third optical adjustment opening 523 and the second fourth optical adjustment opening 524 are both rectangular, a long side of the orthogonal projection of the second third optical adjustment opening 523 is parallel to the first direction X, a short side of the orthogonal projection of the second third optical adjustment opening 523 is parallel to the second direction Y, a long side of the orthogonal projection of the second fourth optical adjustment opening 524 is parallel to the second direction Y, and a short side of the orthogonal projection of the second fourth optical adjustment opening 524 is parallel to the first direction X.

Specifically, in the embodiment shown in FIG. 18, the second optical adjustment openings 52 include a second third optical adjustment opening 523 and a second fourth optical adjustment opening 524. On the plane where the substrate is located, the orthographic projection of at least one second third optical adjustment opening 523 is located between the orthographic projections of the first pixel opening 301 and the third pixel opening 303 arranged alternately along the first direction X, and the orthographic projection of at least one second fourth optical adjustment opening 524 is located between the orthographic projections of the first pixel opening 301 and the third pixel opening 303 arranged alternately along the second direction Y.

On the plane where the substrate is located, the orthogonal projections of the second third optical adjustment opening 523 and the second fourth optical adjustment opening 524 are both rectangular, a long side of the orthogonal projection of the second third optical adjustment opening 523 is parallel to the second direction Y, a short side of the orthogonal projection of the second third optical adjustment opening 523 is parallel to the first direction X, a long side of the orthogonal projection of the second fourth optical adjustment opening 524 is parallel to the first direction X, and a short side of the orthogonal projection of the second fourth optical adjustment opening 524 is parallel to the second direction Y.

It is understandable that FIG. 17 and FIG. 18 are only exemplary. In other optional embodiments, the orthographic projection of only one second third optical adjustment opening 523 is located between the orthographic projections of the first pixel opening 301 and the third pixel opening 303 arranged alternately along the first direction X, or the orthographic projections of three or more second third optical adjustment openings 523 are located between the orthographic projections of the first pixel opening 301 and the third pixel opening 303 arranged alternately along the first direction X; the orthographic projection of only one second fourth optical adjustment opening 524 is located between the orthographic projections of the first pixel opening 301 and the third pixel opening 303 arranged alternately along the second direction Y, or the orthographic projections of three or more second fourth optical adjustment openings 524 are located between the orthographic projections of the first pixel opening 301 and the third pixel opening 303 arranged alternately along the second direction Y.

In some embodiments, as shown in FIG. 19, the first optical adjustment layer 5 includes an optical adjustment structure 53. On the plane where the substrate is located, the orthogonal projection of the optical adjustment structure 53 forms a first enclosed area, the orthogonal projection of the second optical adjustment opening 52 forms a second enclosed area, the orthogonal projection of the first optical adjustment opening 51 is located inside the orthogonal projection of the optical adjustment structure 53, and the orthogonal projection of the optical adjustment structure 53 is located is located inside the orthogonal projection of the second optical adjustment opening 52.

The second optical adjustment opening 52 surrounds the first optical adjustment opening 51 and the pixel opening 30, so that the second optical adjustment opening 52 can uniformly improve all the emitted light of the light-emitting unit in one pixel opening 30, and uniformly improve the large-angle brightness attenuation speed of the light-emitting unit in one pixel opening 30 in each direction, further improving the display effect of the display panel.

In the embodiment shown in FIG. 19, there is no optical adjustment structure 53 arranged around the second pixel opening 302 because the optical adjustment structures 53 arranged around the first pixel opening 301 and the third pixel opening 303 has formed the second optical adjustment openings 52 between the first pixel opening 301 and the second pixel opening 302 and between the third pixel opening 303 and the second pixel opening 302, so it is not necessary to arrange the optical adjustment structure 53 around the second pixel opening 302. In other optional embodiments, in order to increase the number of second optical adjustment openings 52 in the display panel, an optical adjustment structure 53 may also be arranged around the second pixel opening 302, all of which are within the protection scope of the embodiments in the present disclosure.

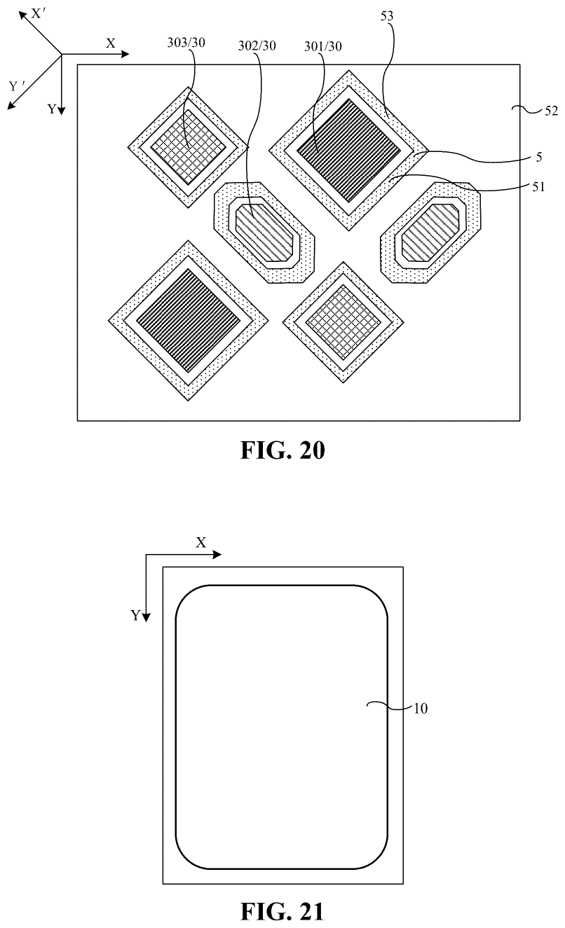

In some embodiments, as shown in FIG. 20, on the plane where the substrate is located, the orthographic projections of a plurality of second optical adjustment openings are interconnected, that is, only the optical adjustment structure 53 arranged around the pixel opening 30 in the first optical adjustment layer 5 is retained, and only part of the emitted light of the light-emitting unit in the pixel opening 30 is deflected toward the normal viewing angle. While adjusting the brightness attenuation degree of the light-emitting unit at a large viewing angle by the optical adjustment structure 53, the normal viewing angle light effect of the display panel is improved, and the brightness of each light-emitting unit at a large viewing angle can also be prevented from being severely attenuated.

It should be noted that in the related art, there is no unified standard for the final display effect of the display panel. According to the different needs of users, the color trajectory of the final display panel shipped can still deviate according to customer needs, and the direction of the deviation can also be different. Therefore, those skilled in the art can select a specific implementation method according to specific needs based on the above multiple embodiments of the present disclosure and their corresponding technical effects, and can also combine the above embodiments of the present disclosure to obtain superimposed technical effects, which are all within the protection scope of the embodiments of the present disclosure.

Based on the same inventive concept, corresponding to the display panel of any of the above embodiments, the present application also provides a display apparatus, as shown in FIG. 21, including the display panel 10 in the above embodiments.

In the embodiments of the present disclosure, the brightness attenuation degree of the light-emitting unit at other viewing angles rather than the normal viewing angle, especially at a large viewing angle can be improved by adding a new second optical adjustment opening on the basis of the original first optical adjustment opening, thereby optimizing the white light color trajectory of the display panel and improving the display effect of the display panel in the display apparatus at a large viewing angle.

Specifically, the above display apparatus may be a 3C electronic product of the type of computer (Computer) and its peripherals, communication and consumer electronics (Consumer Electronics), such as a smart phone, a laptop computer, a tablet computer, a smart wearable device, a home appliance, a gaming device, etc. In addition, the above display apparatus may also be applied to other types of electronic devices such as automotive electronics.

The display apparatus of the above embodiment has the beneficial effects of the corresponding display panel embodiment, which will not be repeated here. It should be noted that, in the present disclosure, relational terms such as “first” and “second” are only used to distinguish one entity or operation from another entity or operation, and do not necessarily require or imply any such actual relationship or order between these entities or operations. Moreover, the terms “include”, “comprises” or any other variation thereof are intended to cover non-exclusive inclusion, so that a process, method, article or device including a series of elements includes not only those elements, but also other elements not explicitly listed, or also includes elements inherent to such process, method, article or device. In the absence of further restrictions, the elements defined by the sentence “including one . . . ” do not exclude the presence of other identical elements in the process, method, article or device including the above elements.

The above are only specific embodiments of the present disclosure, so that those skilled in the art can understand or implement the present disclosure. Various modifications to these embodiments will be obvious to those skilled in the art, and the general principles defined herein can be implemented in other embodiments without departing from the gist or scope of the present disclosure. Therefore, the present disclosure will not be limited to the embodiments described above, but will conform to the widest scope consistent with the principles and novel features disclosed herein.

What is claimed is:

1. A display panel, comprising:
a substrate;
a pixel definition layer located on a side of the substrate, the pixel definition layer comprising a plurality of pixel openings;
a plurality of light-emitting units each at least partially located in the pixel opening;
a first optical adjustment layer located on a side of the light-emitting unit away from the substrate;
a second optical adjustment layer located on a side of the first optical adjustment layer away from the substrate, a refractive index of the second optical adjustment layer being greater than a refractive index of the first optical adjustment layer,
wherein the first optical adjustment layer comprises a plurality of first optical adjustment openings and a plurality of second optical adjustment openings; in a direction perpendicular to a plane where the substrate is located, each of the first optical adjustment openings at least partially overlap one of the pixel openings; and on the plane where the substrate is located, an orthographic projection of each of the second optical adjustment openings is at least partially located between orthographic projections of adjacent two of the pixel openings.

2. The display panel according to claim 1, wherein on the plane where the substrate is located, at least one edge of an orthographic projection of the first optical adjustment opening is parallel to at least one edge of an orthographic projection of the adjacent second optical adjustment opening.

3. The display panel according to claim 1, wherein on the plane where the substrate is located, orthographic projections of at least two of the second optical adjustment openings are between orthographic projections of two of the pixel openings.

4. The display panel according to claim 1, wherein sidewalls of the first optical adjustment openings and the second optical adjustment openings comprise curved sidewalls protruding toward the second optical adjustment layer.

5. The display panel according to claim 4, wherein at least one tangent line of the curved sidewall and the plane where the substrate is located form an included angle in a range of 65° to 85°.

6. The display panel according to claim 4, wherein the display panel further comprises at least one intermediate medium layer that is located between the first optical adjustment layer and the pixel definition layer;
in a preset direction, a distance d between an edge of one of the second optical adjustment openings and an edge of the pixel opening corresponding to the adjacent first optical adjustment opening is in a value range of:
$$x + {\sum }_{i = 1}^{k} {h}_{i} * tan ( asin ( sin ( θ 1 ) / {n}_{i} ) ) \leq d \leq x + {\sum }_{i = 1}^{k} {h}_{i} * tan ( asin ( sin ( θ2 ) / {n}_{i} ) )$$
where x is a length of the curved sidewall in the preset direction, k is a number of the intermediate medium layers, hᵢ is a thickness of the i-th layer of the intermediate medium layers, nᵢ is a material refractive index of the i-th layer of the intermediate medium layers, θ1 is a lower limit of an optical adjustment angle, θ2 is an upper limit of an optical adjustment angle, θ1≤θ2, a value range of θ1 is 55° to 65°, a value range of θ2 is 80° to 90°, and the preset direction is parallel to the plane where the substrate is located and points from the second optical adjustment opening to the adjacent first optical adjustment opening.

7. The display panel according to claim 1, wherein the pixel openings comprise a first pixel opening and a second pixel opening that are adjacent, and on the plane where the substrate is located, an area of an orthographic projection of the first pixel opening is different from an area of an orthographic projection of the second pixel opening;
the second optical adjustment openings comprise a second first optical adjustment opening, and on the plane where the substrate is located, an orthographic projection of the second first optical adjustment opening is located between an orthographic projection of the first pixel opening and an orthographic projection of the second pixel opening;
on the plane where the substrate is located, a distance between an edge of the orthographic projection of the second first optical adjustment opening close to the first pixel opening and an edge of the orthographic projection of the first pixel opening close to the second first optical adjustment opening is a first distance, and a distance between an edge of the orthographic projection of the second first optical adjustment opening close to the second pixel opening and an edge of the orthographic projection of the second pixel opening close to the second first optical adjustment opening is a second distance, the first distance being different from the second distance.

8. The display panel according to claim 7, wherein on the plane where the substrate is located, an area of the orthographic projection of the first pixel opening is larger than an area of the orthographic projection area of the second pixel opening; and
the first distance is smaller than the second distance.

9. The display panel according to claim 7, wherein a red light-emitting unit or a blue light-emitting unit is located in the first pixel opening, and a green light-emitting unit is located in the second pixel opening.

10. The display panel according to claim 1, wherein the pixel openings comprise a first pixel opening, a second pixel opening and a third pixel opening, the first pixel opening and the third pixel opening both are adjacent to the second pixel opening; and
on the plane where the substrate is located, an area of an orthographic projection of the first pixel opening is larger than an area of an orthographic projection of the third pixel opening, and the area of the orthographic projection of the third pixel opening is larger than an area of an orthographic projection of the second pixel opening.

11. The display panel according to claim 10, wherein the second optical adjustment openings comprise a second first optical adjustment opening and a second second optical adjustment opening;
on the plane where the substrate is located, an orthographic projection of the second first optical adjustment opening is located between an orthographic projection of the first pixel opening and an orthographic projection of the second pixel opening, and an orthographic projection of the second second optical adjustment opening is located between an orthographic projection of the third pixel opening and the orthographic projection of the second pixel opening; and
on the plane where the substrate is located, an area of the orthographic projection of the second first optical adjustment opening is larger than an area of the orthographic projection of the second second optical adjustment opening.

12. The display panel according to claim 10, wherein the second optical adjustment openings comprise a second first optical adjustment opening and a second second optical adjustment opening;
on the plane where the substrate is located, an orthographic projection of the second first optical adjustment opening is located between an orthographic projection of the first pixel opening and an orthographic projection of the second pixel opening, and an orthographic projection of the second second optical adjustment opening is located between an orthographic projection of the third pixel opening and the orthographic projection of the second pixel opening; and
on the plane where the substrate is located, a distance between an edge of the orthographic projection of the second first optical adjustment opening close to the first pixel opening and an edge of the orthographic projection of the first pixel opening close to the second first optical adjustment opening is a third distance, and a distance between an edge of the orthographic projection of the second second optical adjustment opening close to the third pixel opening and an edge of the orthographic projection of the third pixel opening close to the second second optical adjustment opening is a fourth distance, the third distance being smaller than the fourth distance.

13. The display panel according to claim 10, wherein a green light-emitting unit is located in the second pixel opening, a red light-emitting unit is located in the third pixel opening, and a blue light-emitting unit is located in the first pixel opening.

14. The display panel according to claim 10, wherein the third pixel openings and the first pixel openings are arranged alternately along a first direction and a second direction each, the third pixel openings and the second pixel openings are arranged alternately along a third direction, the first pixel openings and the second pixel openings are arranged alternately along a fourth direction, and the first direction, the second direction, the third direction and the fourth direction intersect with each other.

15. The display panel according to claim 14, wherein on the plane where the substrate is located, an orthographic projection of one of the second optical adjustment openings is located between orthographic projections of two of the second pixel openings, and the orthographic projection of one of the second optical adjustment openings is located between the orthographic projection of the first pixel opening and the orthographic projection of the third pixel opening.

16. The display panel according to claim 14, wherein on the plane where the substrate is located, orthographic projections of at least two of the second optical adjustment openings are located between the orthographic projections of two of the second pixel openings, and orthographic projections of at least two of the second optical adjustment openings are located between the orthographic projection of the first pixel opening and the orthographic projection of the third pixel opening.

17. The display panel according to claim 14, wherein the second optical adjustment openings comprise a second third optical adjustment opening and a second fourth optical adjustment opening;
on the plane where the substrate is located, an orthographic projection of at least one of the second third optical adjustment openings is located between two respective orthographic projections of the first pixel openings and the third pixel openings arranged alternately along the first direction, and an orthographic projection of at least one of the second fourth optical adjustment openings is located between two respective orthographic projections of the first pixel openings and the third pixel openings arranged alternately along the second direction; and
on the plane where the substrate is located, the orthographic projections of the second third optical adjustment opening and the second fourth optical adjustment opening are both rectangular, a long side of the orthographic projection of the second third optical adjustment opening is parallel to the first direction, a short side of the orthographic projection of the second third optical adjustment opening is parallel to the second direction, a long side of the orthographic projection of the second fourth optical adjustment opening is parallel to the second direction, and a short side of the orthographic projection of the second fourth optical adjustment opening is parallel to the first direction.

18. The display panel according to claim 1, wherein the first optical adjustment layer comprises an optical adjustment structure, and on the plane where the substrate is located, an orthographic projection of the optical adjustment structure forms a first enclosed area, the orthographic projection of the second optical adjustment opening forms a second enclosed area, the orthographic projection of the first optical adjustment opening is located inside the orthographic projection of the optical adjustment structure, and the orthographic projection of the optical adjustment structure is located inside the orthographic projection of the second optical adjustment opening.

19. The display panel according to claim 18, wherein orthographic projections of a plurality of the second optical adjustment openings on the plane where the substrate is located are interconnected.

20. A display apparatus, comprising a display panel comprising:
a substrate;
a pixel definition layer located on a side of the substrate, the pixel definition layer comprising a plurality of pixel openings;
a plurality of light-emitting units each at least partially located in the pixel opening;
a first optical adjustment layer located on a side of the light-emitting unit away from the substrate;
a second optical adjustment layer located on a side of the first optical adjustment layer away from the substrate, a refractive index of the second optical adjustment layer being greater than a refractive index of the first optical adjustment layer,
wherein the first optical adjustment layer comprises a plurality of first optical adjustment openings and a plurality of second optical adjustment openings; in a direction perpendicular to a plane where the substrate is located, each of the first optical adjustment openings at least partially overlap one of the pixel openings; and on the plane where the substrate is located, an orthographic projection of each of the second optical adjustment openings is at least partially located between orthographic projections of adjacent two of the pixel openings.
